(19) United States
(12) Patent Application Publication
(10) Pub. No.: US 2017/0102345 A1
(43) Pub. Date: Apr. 13, 2017

(54) MODULAR NUCLEAR MAGNETIC RESONANCE-DIGITAL MICROFLUIDIC SYSTEM FOR BIOLOGICAL ASSAYS

(71) Applicant: UNIVERSITY OF MACAU, TAIPA (CN)

(72) Inventors: Ka-Meng LEI, Taipa (CN); Pui-ln MAK, Taipa (CN); Man-Kay LAW, Taipa (CN); Rui Paulo DA SILVA MARTINS, Taipa (CN)

(73) Assignee: UNIVERSITY OF MACAU, TAIPA (CN)

(21) Appl. No.: 14/881,615

(22) Filed: Oct. 13, 2015

(51) Int. Cl. G01N 24/08; G01R 33/46; G01R 33/465

(52) U.S. Cl. CPC G01N 24/087; G01R 33/465; G01R 33/4625

(57) ABSTRACT

A portable modular NMR-DMF system for performing chemical/biological assays. The system comprises a PCB having an NMR electronic circuit thereon, wherein the NMR electronic circuit includes a figure-8 shaped RF coil generating a plane-parallel magnetic field. A planar DMF chip comprises a platform comprising an array of electrodes, the array of electrodes including a sensing site located under the figure-8 shaped RF coil. A portable magnet is disposed parallel to the DMF chip and the RF coil. The array of electrodes is configured to receive a sample under detection, move the sample along the array, mix the sample with a probe in the form of at least one droplet with target-specific nanoparticles, and move the mixed sample to the sensing site. A magnetic field corresponding to the mixed sample under detection is produced at the sensing site. The figure-8 shaped RF coil acts to transduce the magnetic field produced at the sensing site to a voltage signal. The NMR electronic circuit receives and processes the voltage signal to produce a resultant signal for analysis.

### BACKGROUND OF THE INVENTION

Field of the Invention

The present invention generally relates to a modular nuclear magnetic resonance-digital microfluidic system, method, and apparatus and program (NMR-DMF) for chemical/biological assays.

Related Art

Portable point-of-care (POC) diagnostic tools have become an attractive approach for global healthcare, especially for under-developed countries where advanced low-cost diagnostic tools are very limited. In fact, for infectious diseases, e.g., human immunodeficiency virus (HIV) or tuberculosis, retard in diagnosis can worsen the situations in both individual and community levels.

A wide variety of point-of-care diagnosis tools have been available, such as tools incorporating impedance and capacitance sensing, both relying on a pair of electrodes (transducers) to quantify the chemical/biological targets between them. Furthermore, with pre-designed probes and magnetic beads, magnetic sensing is another way to detect the targets. Still further, bio-luminance detection is one more option sensing the amount of luminance emitted during the reaction of bioparticles such as pathogens and antigens.

Apart from those methods, nuclear magnetic resonance (NMR) is considered as a new tool for diagnosis. Traditionally, NMR was used as an analyzing tool for molecules structure and chemical kinetics. Recent works on NMR have successfully detected a number of biological targets such as oligonucleotide, protein, Mycobacterium tuberculosis, and bladder cancer cells using a palm-size permanent magnet. In addition, with the advance of micro-electronics, NMR circuitry can be miniaturized in size while upholding adequate sensitivity suitable for a wide variety of chemical/biological assays.

The underlying principle of NMR detection is to sense the NMR signal from the samples, which are mixed with target-specific magnetic-nanoparticles. The presence of the target in the samples will lower the spin-spin relaxation time (T₂), indicating the existence of the target rapidly in real-time.

However, the inventors of the present application have observed a number of challenges of NMR as detailed herein. There exists, therefore, a need to provide a novel system, method, apparatus, and program that overcomes the drawbacks of the existing methods.

### SUMMARY OF THE INVENTION

The inventors of the present application observe that one major challenge of micro-scale NMR is the operation of tiny samples beforehand that can involve multi-step multi-site treatments. The samples under detection must be mixed with the specific probes in one place, and re-positioned to the sensing site inside the magnet for NMR. These procedures, regrettably, rely heavily on human efforts, degrading the throughput and consistency of diagnosis results, while raising the chance of contamination. To address this issue, certain efforts have been undertaken to facilitate sample manipulation in NMR systems, such as capillary electrophoresis and microfluidic channels. Still, the inventors observe that these methods involve several laboratory accessories (e.g., pumps and pressure generators) and fixed fluidic paths/pipes that have low portability and re-configurability.

In contrast, the inventors note that digital microfluidics (DMF) devices appear as a handy electronic-automated platform, thereby allowing flexible droplet operations on a planar electrode array. By exploiting the principle of electrowetting-on-dielectric (EWOD) to modify the surface tension, droplets can be guided and transported freely over the electrodes. Unlike the channel microfluidic devices the routing paths of droplets in DMF can be customized and re-programmed by a computer program, opening up much design flexibility to manage droplets such as transporting, mixing, and splitting. In addition, as the DMF chip is planar, all droplets can be preloaded on chip before routinely executing the reaction or screening, thereby enhancing the consistency of the experiments.

The present invention in one aspect discloses the first lab-on-a-chip module unifying nuclear magnetic resonance and digital microfluidics (NMR-DMF) with simple electronics and a portable magnet, allowing non-invasive magnetic resonance diagnosis atop the DMF chip in real-time. One of the key challenges of integrating NMR on DMF is the geometrical limitation of the portable magnet. The present invention manages to overcome this by introducing a figure-8 shaped coil such that the magnet can be placed parallel to the DMF chip and RF coil for better use of the inner space of the magnet. To demonstrate that the system is capable of performing biological assays in a fully autonomous fashion, biotinylated magnetic nanoparticles were selected as the probe to detect the existence of avidin in the droplet samples. Results showed that the system can transport and mix the samples and probes over the DMF chip successfully. This portable NMR-DMF system can be broadly applicable to small-sample biological analyses.

The present invention in one aspect provides a portable modular Nuclear Magnetic Resonance-Digital Microfluidic (NMR-DMF) system for performing chemical/biological assays. The system comprises a printed circuit board (PCB) having an NMR electronic circuit thereon, wherein the NMR electronic circuit includes a figure-8 shaped RF coil generating a plane-parallel magnetic field. A planar DMF chip comprises a platform comprising an array of electrodes using electro-wetting-on-dielectric (EWOD) effects, the array of electrodes including a sensing site located under the figure-8 shaped RF coil and having top and bottom planes for squeezing droplets. A portable magnet is disposed parallel to the DMF chip and the RF coil. In the planar DMF chip a first electrode in the electrode array is configured to initially receive a sample under detection, and a last electrode in the electrode array is configured to act as the sensing site and to initially receive a probe in the form of at least one droplet with target-specific nanoparticles. The planar DMF chip is configured to transport a sample under detection from the first electrode to the sensing site using an operation sequence including (1) initially applying a signal on the first electrode, then (2) turning off the first electrode thereby moving the sample to a subsequent electrode, and (3) repeating said operation sequence to ultimately move the sample to the sensing site after a mixing sequence. The planar DMF chip uses the mixing sequence to mix the sample with the probe placed on the sensing site before the mixed sample is finally moved to the sensing site. A magnetic field corresponding to the mixed sample under detection is produced at the sensing site. The figure-8 shaped RF coil serves as an interface between the mixed sample at the sensing site and the NRM electronic circuit and acts to transduce the magnetic field produced at the sensing site to a voltage signal. The NMR electronic circuit receives and processes the voltage signal to produce a resultant signal for analysis.

The operation sequence may further include surrounding the sample with silicone oil when the sample is initially placed on the first electrode. The steps of the operation sequence may be stored in a computer program embodied in a non-transitory computer-readable medium for execution by a processor.

The mixing sequence may include: (1) mixing the probe with the sample to form the mixed sample when the sample reaches the penultimate electrode, (2) shuffling the mixed sample between (a) the electrode located before the penultimate electrode and (b) the last electrode a plurality of times for more thorough mixing, and (3) finally transporting the mixed sample to the last electrode for NMR sensing. The steps of the mixing sequence may be stored in a computer program embodied in a non-transitory computer-readable medium for execution by a processor.

The array of electrodes on the platform of the planar DMF chip may have 8 electrodes. The electrodes in the array of the DMF chip may be formed of chromium. Each electrode in the array may be driven by a square wave driving signal while each neighboring electrode is grounded to prevent excess charges stored in the electrodes. The system may further comprise at least one additional figure-8 shaped RF coil corresponding to at least one additional planar DMF chip for simultaneous sensing at multiple sites.

The figure-8 shaped RF coil may be comprised of two spiral coils in reverse direction in series. The figure-8 shaped RF coil may have a sensitive region midway between the two spiral coils that is configured to be covered by the sample.

The present invention in another aspect provides a portable modular Nuclear Magnetic Resonance-Digital Microfluidic (NMR-DMF) system for performing chemical/biological assays. The system comprises a printed circuit board (PCB) having an NMR electronic circuit thereon, wherein the NMR electronic circuit includes a figure-8 shaped RF coil generating a plane-parallel magnetic field. A planar DMF chip comprises a platform comprising an array of electrodes, the array of electrodes including a sensing site located under the figure-8 shaped RF coil. A portable magnet is disposed parallel to the DMF chip and the RF coil. The array of electrodes is configured to receive a sample under detection, move the sample along the array, mix the sample with a probe in the form of at least one droplet with target-specific nanoparticles, and move the mixed sample to the sensing site. A magnetic field corresponding to the mixed sample under detection is produced at the sensing site. The figure-8 shaped RF coil acts to transduce the magnetic field produced at the sensing site to a voltage signal. The NMR electronic circuit receives and processes the voltage signal to produce a resultant signal for analysis.

The present invention in another aspect provides a method for performing chemical/biological assays using a portable modular Nuclear Magnetic Resonance-Digital Microfluidic (NMR-DMF) system comprising a printed circuit board (PCB) having an NMR electronic circuit thereon, wherein the NMR electronic circuit includes a figure-8 shaped RF coil generating a plane-parallel magnetic field; a planar DMF chip comprising a platform comprising an array of electrodes, the array of electrodes including a sensing site located under the figure-8 shaped RF coil; and a portable magnet disposed parallel to the DMF chip and the RF coil. The method comprising the steps of placing a sample at a first electrode in said array of electrodes, moving the sample along the array, mixing the sample with a probe in the form of at least one droplet with target-specific nanoparticles, moving the mixed sample to the sensing site at a last electrode of said array, producing a magnetic field corresponding to the mixed sample under detection at the sensing site, transducing by the figure-8 shaped RF coil the magnetic field produced at the sensing site to a voltage signal, and processing the voltage signal by the NMR electronic circuit to produce a resultant signal for analysis.

The present invention in another aspect provides a non-transitory computer-readable medium storing a program which, when executed by at least one processor, performs a method for performing chemical/biological assays using a portable modular Nuclear Magnetic Resonance-Digital Microfluidic (NMR-DMF) system comprising a printed circuit board (PCB) having an NMR electronic circuit thereon, wherein the NMR electronic circuit includes a figure-8 shaped RF coil generating a plane-parallel magnetic field; a planar DMF chip comprising a platform comprising an array of electrodes, the array including a sensing site located under the figure-8 shaped RF coil, a first electrode in the array being configured to initially receive a sample under detection and a last electrode in the array being configured to act as the sensing site and to initially receive a probe in the form of at least one droplet with target-specific nanoparticles; and a portable magnet disposed parallel to the DMF chip and the RF coil. The method comprises the steps of performing an operation sequence comprising applying a signal on the first electrode and then turning off the first electrode thereby moving the sample to a subsequent electrode; repeating the operation sequence for each subsequent electrode to move the sample to a penultimate electrode; performing a mixing sequence to (1) mix the probe with the sample to form the mixed sample when the sample reaches the penultimate electrode, and (2) shuffle the mixed sample between (a) the electrode located before the penultimate electrode and (b) the last electrode a plurality of times for more thorough mixing; and transporting the mixed sample to the last electrode for NMR sensing.

Further features and advantages of the present invention as well as the structure and operation of various example embodiments of the present invention are described in detail below with reference to the accompanying drawings.

### BRIEF DESCRIPTION OF THE DRAWINGS

The features and advantages of the present invention will be more readily understood from a detailed description of the exemplary embodiments taken in conjunction with the following figures:

FIG. 1, which includes FIGS. 1(a) to 1(e), shows the overall schematics and operations of an NMR-DMF system 10 according to one embodiment of the present invention.

FIG. 1(a) shows the placement of the DMF chip 12, magnet 14, RF coil 16, and PCB board 18 in a 3D view. Due to the benefit from the plane-parallel magnetic field generated by the figure-8 shaped coil 16, the NMR system can be effectively integrated into the DMF system.

FIG. 1(b) illustrates schematics of the NMR Electronics 20. The transmitter 22 which is formed by the digital logics such as flip flops is used to excite the hydrogen atom. On the receiver part 24, the capacitor together with the RF-coil (fabricated figure-8 shaped coil) 16 forms an LC tank to provide passive gain enhancing of the system's sensitivity. The signal is then amplified and down-converted to f_{IF} (intermediate frequency) and fed to the external filters and oscilloscope 26.

FIG. 1(c) shows that the filtered results from the PCB 18 (Printed Circuit Board) are captured by the oscilloscope 26 for easier demonstration purpose. Waveforms are then analysed and the spin-spin relaxation time (T₂) is fitted by the algorithm written for example in MATLAB.

FIG. 1(d) shows the DMF chip and the structure of the DMF platform. The droplets are squeezed between the top and bottom planes and surrounded by silicone oil.

FIG. 1(e) shows the detection mechanism of the NMR-DMF system. The target-specific magnetic nanoparticles, which act as probes, are placed on the sensing site initially. The samples at other electrodes (in cyan) will be transported to the sensing site and mixed with the probes to perform NMR assays automatically by applying voltage on corresponding electrodes. Without the target, the probes stay monodispersed and will have a longer T₂. Otherwise, the target and probes will form clusters by forming bonds between each other and the T₂ will be decreased.

FIG. 2(a) is an illustration of a conventional spiral coil. The magnetic field generated by the current as shown in the figure will have a direction out of the paper. The shape of the coil is typically circular in order to enhance the magnetic field at the center.

FIG. 2(b) illustrates the placement of the magnet and the conventional spiral coil. Due to the fact that the RF field from the coil and the magnetic field from the magnet must be orthogonal to each other, the spiral coil and magnet must be configured as shown in the figure, which is not suitable for the DMF platform.

FIG. 2(c) is an illustration of the figure-8 shaped coil 16 according to an embodiment of the present invention. Generally it is composed by two spiral coils in reversed direction (CW and ACW) in series, and the field between two coils generated by the current shown in figure will have a direction pointing downward and it is the sensing region in the system of the present invention. The shape of a single coil is square instead of circular in this embodiment to enhance the magnetic field at the sensitive region.

FIG. 2(d) illustrates the placement of the magnet and the figure-8 shaped coil 16 according to an embodiment of the present invention. Since the magnetic field is parallel to the PCB substrate direction, the magnet 14 and the coil 16 now can be placed as shown in the figure and the DMF platform can be effectively integrated with the NMR.

FIG. 3(a) is a plot of unit magnetic field in the y-direction of the 14-turn figure-8 shaped coil 16 along the z-axis. The magnetic field is stronger on the coil surface (1.8 mT) and starts to decrease above the coil 16. The inset shows a photograph of the 14-turn figure-8 shaped coil 16 according to one embodiment.

FIG. 3(b) illustrates the magnetic flux lines of the simulated 14-turn figure-8 shaped coil 16. The magnetic fluxes are still pointing in the z-direction at the centers of each coil. However, between the two coils, the magnetic flux is pointing in the y-direction, generating plane-parallel magnetic flux.

FIG. 4 illustrates a Nutation curve of the 14-turn figure-8 shaped coil 16. The normalized amplitude from the different duration of RF excitation signals was recorded and fitted to the sinusoidal wave. The estimated π/2 pulse widths for the coil is 144 μs.

FIG. 5(a) illustrates a received NMR signal from water. The received signal is composed by trains of echoes induced by the CPMG pulses. The glitches between the echoes are the excitation pulses. Usually the first echo is neglected for relaxation time derivation since it is interfered by a different coherence pathway. The inset shows the enlarged received NMR signal. The echoes are clear and their peak-to-peak amplitudes were plotted on the right against time, with a decreasing exponential manner, which was bounded by the grey dotted trend line. The derived relaxation time by the algorithm in this case is 343.6 ms.

FIG. 5(b) illustrates the transverse relaxation time of the NMR signal versus concentration of CuSO₄ solution and the results were shown on the graph (▪). The trend lines were drawn together with their equation and R² value. 95% confidence levels were marked on the graph (-). In addition, the error percentages (defined as half of 95% confidence level/true value) are marked on the graph with dot lines where the values were displayed on the axis on the right.

FIG. 6 shows the percentage of Eddy current loss generated by the 14-turn figure-8 shaped coil 16 to coil magnetic energy against the thickness of the ITO glass. The figure was plotted based on (4) with f=20 MHz, ρ=1×10⁻⁶ Ωm, A=40 mm×24 mm, which is 4 times the dimension of the figure-8 shaped coil. B_{RF} is the magnetic field on the ITO. For accurate prediction, B_{RF} should vary according to the relative position of the ITO compared to the coil. Here only the peak magnetic field at the position of ITO (which is 1.5 mT from FIG. 3) is substituted. The dot line shows 0.5% level and corresponding to the ITO thickness of 80 nm.

FIG. 7(a) shows a fabricated DMF chip. For illustration, the electrodes are numbered 1-8.

FIGS. 7(b) and 7(c) show operation of the DMF platform. The droplet was originally placed at electrode no. 1 (highlighted by the circle). By applying the signal on electrode no. 2 and then turning off electrode no. 1, the droplet moved to electrode no. 2. As such, the droplet can be transported to electrode no. 8, which is the NMR sensing site.

FIG. 8(a) is an illustration of droplets mixing. The droplets at electrode no. 1 (samples) and no. 8 (probe) were driven to electrode no. 7 and mixed together.

FIG. 8(b) shows the NMR assay results from the mixed droplets. Biotinylated magnetic nanoparticles acted as a probe. If the samples do not contain avidin, the nanoparticles will stay monodispersed and a longer T₂ will be obtained (181.5 ms). If avidin is in the samples, avidin and biotin will combine to form a rigid bond and clusters will be presented. Consequently, T₂ will be decreased by the perturbation of the magnetic nanoparticle clusters (86.13 ms). This shows that the system is capable of detecting the existence of protein in the samples in a fully-automated way.

FIG. 9 is a plane-parallel magnetic flux density map of the 14-turn figure-8 shaped coil 16 at z=0.6 mm (the depth of the ITO glass). The sensing region, which is defined as the area having a plane-parallel magnetic flux density larger than 50% its peak value (1.43 mT), is located between the centers of two coils and has the shape of a circle with a diameter of around 4.2 mm.

FIG. 10(a) shows the measured gain of an NMR receiver according to an example embodiment of the present invention.

FIG. 10(b) shows the measured output spectrum of a receiver with a 100 nV, 20 MHz sinusoidal input according to an example embodiment of the invention.

FIG. 10(c) shows a received NMR signal of water. The T₂ extraction result (431.0 ms) shows that it is similar to the case without the DMF platform. This indicates that the system performs at least as well as a conventional NMR system.

The invention will next be described in connection with certain exemplary embodiments; however, it should be clear to those skilled in the art that various modifications, additions, and subtractions can be made without departing from the spirit or scope of the claims.

### DETAILED DESCRIPTION OF THE PREFERRED EMBODIMENTS

### 1. Brief Overview

The present invention in one example aspect is directed to a modular nuclear magnetic resonance-digital microfluidics (NMR-DMF) system, method, apparatus, and program as or involving a portable diagnostic platform for miniaturized chemical/biological assays. With increasing numbers of combination between designed probes and a specific target, NMR can be an accurate and rapid assay tool capable of detecting particular kinds of proteins, DNAs, bacteria, and cells with a customized probe quantitatively. Traditional sample operation (e.g., manipulation and mixing) relied heavily on human efforts. The present invention discloses a modular NMR-DMF system, apparatus, method, and program to allow electronic automation of multi-step reaction-screening protocols.

In one example aspect a figure-8 shaped coil is provided to enlarge the usable inner space of a portable magnet by 4.16 times, generating a radio frequency (RF) excitation field in the planar direction. By electronically managing the electro-wetting-on-dielectric (EWOD) effects over an electrode array, preloaded droplets with the inclusion of chemical/biological constituents and targets can be programmed to mix, and be guided to the detection site (3.5×3.5 mm²) for high-sensitivity NMR screening (static B field: 0.46 T, RF field: 1.43 mT per ampere), with the result (voltage signal) displayed in real-time. To show the system's utility, automated real-time identification of 100 pico mole of avidin in a 14 μL droplet was achieved. The system is advantageous as a robust and portable diagnostic device for a wide variety of chemical/biological analyses and screening applications.

### 2. NMR-DMF System Prototype

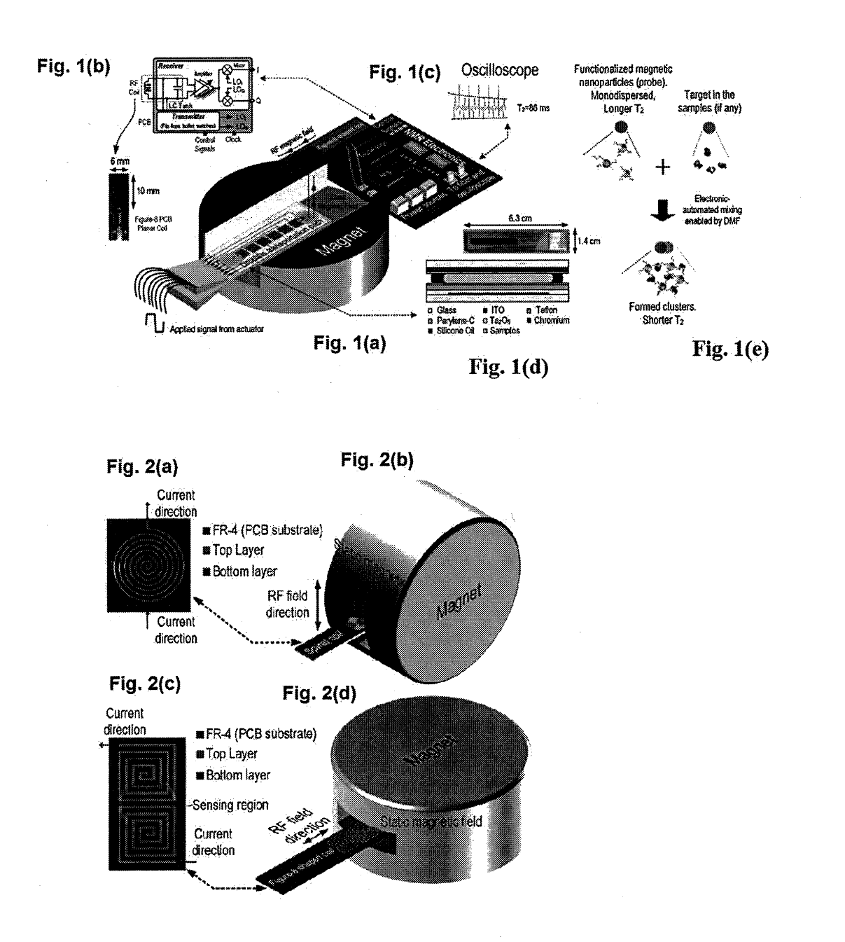

FIG. 1(a) shows an overview of the NMR-DMF system 10 according to one embodiment of the present invention. The system 10 is designed to drive the droplets under detection and target-specific probes, if any, to the desired location for NMR assays. The movement of droplets is handled by an electrode array which was fabricated on the glass substrate. The RF coil 16 functions as a transducer transforming the magnetic field to voltage (or vice versa). The electronics transmits the excitation signal to the RF coil, and receives the NMR signal from it. The results are collected by an oscilloscope 26 in this prototype (for portability, by an analog-to-digital converter to interface with the computer). The relaxation times are derived by a software algorithm. The DMF platform and NMR coils are customized in size to befit the limited inner volume of the magnet. Design considerations of the system are provided as follows.

### 2.1 Nuclear Magnetic Resonance

### Magnet

The portable permanent magnet 14 is responsible for magnetizing the nuclei of the atoms. Atoms such as ¹H, ²H, ¹³C and ¹⁹F can be analysed, but due to the natural abundance stability and commonness of hydrogen atoms (in water), this design only focuses on the hydrogen atoms. The strength of the magnet 14 correlates to the Larmor frequency and the signal-to-noise-ratio (SNR) of the sensed output:

$$\begin{matrix}{ω}_{L} = \frac{fL}{2 π} = {γB}_{0} & ( 1 ) \\ {Ψ}_{rms} {α KB}_{1} \sqrt{( \frac{1}{Fl ξΔ f} ) \frac{{ω L}^{\frac{7}{4}}}{\sqrt[4]{ρ}}} & ( 2 ) \\ & \end{matrix}$$

with gyromagnetic ratio γ, permanent magnet field strength B₀, homogeneity factor K, magnetic field strength per unit current produced by the RF coil 16 orthogonal to the permanent magnet field B₁, noise figure of the receiver's forefront amplifier F, length of the RF-coil conductor 1, bandwidth of the system Δf and resistivity ρ of the RF coil. From equations (1) and (2), the SNR of the system is proportional to power of 7/4 of the magnetic field strength B₀. Although there are numerous ways to enhance the magnetic field (i.e., for higher resolution and lower noise), the portability and power consumption of the system may be diminished due to the need of a heavier and bulkier magnet, and moreover a higher operating frequency would be required for the electronics.

To balance the system performance with its portability, a 0.5 T permanent magnet was chosen for this embodiment. It is 1.25 kg in weight and 1005 cm³ in volume. The corresponding f_{L} of the hydrogen atom under this magnet strength is ˜21 MHz. It is of course to be understood, however, that the present invention is not limited to these examples, and modifications can be made.

### Electronics and Back-End Signal Processing

The electronics of the NMR-DMF system 10 were mainly built with discrete components for fast prototyping and greater flexibility to integrate with the DMF electronics.

The schematic of the electronics is depicted in FIG. 1(b), which mainly consists of two paths: transmitter 22 and receiver 24. Before the nuclear spins can induce signal to the coil, they have to be excited by the coil at f_{L}. Since a Carr-Purcell-Meiboom-Gill (CPMG) sequence is applied, both in-phase (I) and quadrature (Q) waveforms are collected. By applying frequency division, a pair of equal-pulse-width I and Q signals can be generated under a clock-signal frequency 4 times the Larmor frequency. To prevent (or reduce the chance of) the SNR of the system 10 from degrading by the flicker noise of the electronics, the clock frequency was chosen at 4(f_{L}+f_{IF}), with intermediate frequency f_{IF}. Although the excitation frequency is shifted to f_{L}+f_{IF} instead of f_{L}, the atoms can still be excited if f_{IF} is small enough, which also facilitates the design of the electronics. Since the RF coil 16 serves both the transmitter 22 and receiver 24, switches must be used to isolate the excitation signal from leaking to the receiver 24. For the transmitter 22, output buffers were utilized to boost up the driving capability. The operating phases of the switches and buffers are controlled in this embodiment by a field-programmable gate array (FPGA).

The receiver 24 can amplify the weak signal coupling from the RF coils 16. The weak amplitude of the induced NMR signal is at a level of 100 nV to 40 μV. The first amplification is based on an LC tank to provide a passive gain Q to the signal, where Q is the quality factor of the RF coil 16. The noise figure of the receiver 24 will then be suppressed by the Q, and the overall SNR will be increased according to equation (2). The input impedance of the forefront amplifier should be adequately large to prevent its loading effects to the LC tank, which otherwise deteriorate the sensitivity. Obviously, the noise performance of the amplifier is decisive to the SNR of the receiver. In addition, as the signal amplitude is not consistent due to the uncertainties of sample volume and chemical/biological constituents inside the samples, a variable-gain amplifier is necessary for compensation.

After signal amplification, the signal is driven to the I and Q mixers for down-conversion to f_{IF}. This also allows filtering of the high-frequency noise superimposed into the signal. Passive mixers befit this system as they generate less noise than its active counterpart. The resulting signals are then low-pass filtered, and further amplified before driving into a digital oscilloscope [FIG. 1(c)] to reduce the uncertainty due to quantization error. According to equation (2), the bandwidth of the filter should be set carefully to prevent excessive out-of-band noise. Finally, the signals are collected for back-end processing such as I/Q demodulation and T₂ derivation. The echoes amplitude decays exponentially and an algorithm written in MATLAB was built to derive and fit to this exponential curve:

$${A}_{peak} ( t ) = {A}_{o} {e}^{\frac{t}{T 2}} \qquad ( 3 )$$

where Aₚₑₐₖ(t) is the amplitude of the echo at the time t, and A₀ is the original amplitude of the echo. By putting different pairs of values of Aₚₑₐₖ(t) and t, the values of A₀ and T₂ are derived.

### RF Coils

The RF coils 16 are the interface between the droplet samples and electronics. This transduces the magnetic field produced by the hydrogen atoms to voltage for the receiver 24. There are different kinds of coils such as, e.g., a saddle shaped coil, a solenoid, and a planar coil. A saddle shaped coil and a solenoid require either hand-wrapping or an extra fabrication process. A planar coil such as used in this embodiment, on a low-cost two-side printed circuit board (PCB), is appealing for consistency of parameters and disposability under volume production.

Typically the planar coil is circular spiral as shown in FIG. 2(a). The dominant magnetic field of this kind of RF coil is in its axial direction. This spiral coil is common due to its high sensitivity, but the magnetic field from the RF coil has to be orthogonal to the static magnetic field from the magnet, posing a physical limitation on the position of the coil. As illustrated in FIG. 2(b), the PCB coil has to be within the gap (12 mm) of the magnet, limiting the number of electrodes that can be integrated. The inventors of the present application note that one way to surmount this obstacle is to use a single-sided magnet with a surface-parallel magnetic field, where static and RF magnetic fields will be orthogonal to each other. However, this kind of magnet has to be customized, and the magnetic field is weaker when compared with the chosen (0.2 to 0.5 T). In fact, as another dimension of the gap is 50 mm in length, the present invention makes use of a figure-8 shaped coil to resolve this issue, as shown in FIG. 2(c). Here, a square coil is utilized instead to enhance the magnetic field at the boundary. The figure-8 shape means that there are two coils with opposite axial magnetic field direction placed next to each other and connected in series. In this way, the magnetic field coupled between the centers of the two coils will be in-phase and constructively summed, being an effective sensing region of the coil.

With same number of turns per spiral, a figure-8 shaped coil induces more thermal noise than a spiral coil since the length of the conductors is doubled. Referring to equation (2), the SNR will be increased accordingly. However, it has been proven that the figure-8 shaped coil is less susceptible to environmental couplings (e.g., powerline cables, equipment, and RF interference) since they appear as a common-mode noise. In addition, as depicted in FIG. 2(d), the RF-field direction of the sensitive region is parallel to the PCB 18. This implies that the PCB coil 16 can be located horizontally with the gap of the magnet, enlarging the space by 4.16 times for the DMF chip.

### 2.2 Digital Microfluidics

### DMF Platform

DMF is a lab-on-a-chip technology based on the principle of electrowetting-on-dielectric (EWOD). Droplets are manipulated via surface-tension modulation induced by an electric field, enabling electronic-automated chemical/biological reactions with low sample volumes. Differing from the conventional microfluidics, the metallic electrodes, dynamic actuation signal, and discrete droplet controllability constitute a highly-efficient droplet-management POC platform for disease diagnostics. The principle of DMF is to change the contact angle between the droplets and substrate by electric fields. When there is no electric field applied to the electrode under the Teflon layer, the surface of the Teflon is hydrophobic. However, when an electric field is presented, the surface will become hydrophilic. As a result, the droplets can be manipulated easily by voltage signals.

The structure of a DMF platform is shown in FIG. 1(d), and it is composed by an electrode array. The electrodes are formed by Chromium. The ITO (Indium Tin Oxide) acts as a ground plane for the electric fields. Both are coated on a glass substrate. To integrate the NMR and DMF, the DMF chip 12 is sized for inserting into the magnet 14 for magnetizing the samples, and the coil 16 is located atop the samples for high-sensitivity sensing.

However, as the electrode (chromium) and ITO are made by conducting materials, the Q of the coil 16 will be degraded when they are placed near by the coils, due to the eddy currents formed in the conductors. The energy loss per cycle in the conductors by eddy currents (when the skin effect does not take place) is:

$${W}_{loss} = \frac{{( π * BRF * d * f )}^{2}}{6 ρ} * ( A * d ) \qquad ( 4 )$$

with the magnetic field generated by the RF coil 16 on the conductor B_{RF}, the thickness of the conductor d, the cross-section area of the conductor A, the frequency of the magnetic field f, and the resistivity of the conductor ρ. By the law of energy conservation, the energy losses in the conductors are generated from the RF coil 16, causing Q degradation of the coil. To maintain the Q of the coil, the eddy current loss in the nearby conductor must be minimized. The eddy current loss in the chromium is negligible in most cases, as it has sheet resistance >100 Ω/sq. However, for the ITO, attention should be taken since its sheet resistance can vary from 5 to 500 Ω/sq. An ITO with higher sheet resistance may lead to slower droplet motion but will decrease the eddy current loss. Moreover, the SNR of the NMR signal will be reduced with diminishing B₁ according to equation (2), and the eddy current generated by the conductor will diminish the effective B₁. From equation (4), the thickness of the ITO should be optimized to reduce the eddy current loss as it will rise proportionally to the cube of d. Besides, to ensure the droplet movement and reduce the required driving voltage, silicone oil was injected to fill the gap between the ITO layer (top plate) and DMF chip (bottom plate).

### Electrodes Actuator

The driving signal of each electrode is a 50%-duty-cycle square wave in one example embodiment of the invention. To avoid overstress conditions, the driving signals are clipped by a diode protection scheme. To move a droplet to the desired electrode, the driving signal will be connected to the correlated pads while the neighbouring electrode is grounded to prevent excess charges stored in the electrodes that otherwise might cause a dielectric breakdown.

### 3. Materials and Methods

### Permanent Magnets

In one example embodiment magnets PM-1055 were purchased from Metrolab (Switzerland) having a nominal magnetic field of 0.5 T. The actual magnetic field was confirmed by Tesla Meter DTM-150 with probe LPT-130 from Group3 Technology Ltd. (New Zealand) before the NMR experiment took place to ensure that the applying frequency matches with f_{L} given in equation (1). In addition, since the magnet has a temperature coefficient of −1200 ppm/K in this embodiment, the temperature of the testing environment has to be tracked to ensure that the excitation frequency is not shifted from f_{L} after temperature variation. This process was done by a digital thermometer from Agilent (Santa Clara, Calif.).

### Electronics

The electronics detailed in ESI were mounted onto a low-cost PCB 18. The control parts are linked to FPGA DE2 from Altera (San Jose, Calif.). The resulting signal from the PCB 18 was filtered by the low-pass filter SR640 from Stanford Research Systems (Sunnyvale, Calif.). It filters out the high-frequency noise and offers extra signal gain. Finally, the signal was displayed on a digital oscilloscope DS091304A from Agilent. To measure the overall signal gain, a sinusoidal test signal generated from signal generator E4436B, Agilent, was injected into the receiver. The signal coming out from the low-pass filter was connected to a signal analyzer N9030A from Agilent.

### RF Coils

The coil's layouts were drawn via Altium Designer Summer 09 (Australia). The turn spacing and width of the conductor in the coils are both 0.15 mm. The leads of the coils were drawn wider enough to minimize the loss. The copper thickness of the PCB is ˜26 μm. The received coils were characterized by an impedance analyzer 4294A from Agilent. Four samples were measured for each type of coil to demonstrate the reproducibility. The performance and characteristics of the coil are studied by COMSOL™. The strength and direction of the magnetic fields are simulated by injecting 1 A current through the coil.

### Signal Post-Processing

The signal displayed on the oscilloscope 26 were collected and analysed by MATLAB (Natick, Mass.). The peak echo of the signals was detected and fit into the regression model to derive the T₂ of the echo trains.

### Samples

De-ionized water was firstly tested to ensure the functionality of the system. Then different concentrations of Copper sulfate (CuSO₄) diluted from CuSO₄.5H₂O were tested. Bio-assays were performed to ensure the practicability of the system. The bio-samples in this experiment were binding of avidin on cross-linked biotinylated iron nanoparticles and Avidin from MicroMod (Germany). The sizes of the nanoparticles are 100 nm and concentration of Iron nanoparticles is 0.2 mM. The concentration of avidin is 1 mg/mL.

### NMR Settings

The samples volume for the NMR testing alone is 5 μL. The π/2 pulse widths for the coil was first estimated by calculation and then calibrated by observing the amplitude of the free induction decay of the NMR signals. Spacing between the echoes was set to 10 ms for water and CuSO₄ sample and 3 ms for magnetic particles. 30 echoes were collected for each NMR measurements and each measurement was repeated 16 times to enhance the signal SNR. After each measurement, the system halted for 5 secs before the next experiment to ensure the atoms stop vibration and was magnetized stably by the magnet.

### Digital Microfluidics Chip

The ITO glasses were purchased from HuaNan Tehnology Ltd. (China). The thickness of the overall glass was 0.5 mm. The pattern of the electrode was drawn in AutoCad (San Rafael, Calif.). The process of fabrication of the DMF platform was similar to the one stated before. The volume of liquid under testing per electrode (without mixing) is 7 μL. The electrodes were driven by a square wave with a peak-to-peak voltage of 40 V and a frequency of 1 kHz. The size of the electrodes was 3.5×3.5 mm², and the gap between the top and bottom planes was 0.45 mm.

### 4. Experiment and Results

### Magnets

To approximately locate the Larmor frequency of the hydrogen atoms, the field strength of the magnet 14 was first measured. The magnetic field at the center of the magnet 14 was around 0.4615 Tesla at 20° C. This corresponds to a f_{L} of 19.65 MHz.

### RF Coils

Several figure-8 shaped coils were optimized in COMSOL with a three-dimensional model before fabrication to determine the required number of turns. The fabricated coils were measured with an impedance analyzer and compared with the simulations to confirm the parameters. Table 1 shows two sets of parameters for the coil with 14 and 18 turns. The difference between the simulation and measurement results is

TABLE 1
Summary of the measured and simulated figure-8 shaped coil parameters
at 20 MHz. For measurement data 4 coils are measured for each case,
with mean-value together with standard-deviation shown. The results
shows that the coils have high accuracy (<7%) and reproducibility
(<3%). Sims: simulation; Meas: measurement. Parameters: copper
thickness = 26 μm, FR-4 relative permittivity = 4.5.

| Turns | Resistance | | Inductance | | Quality Factor |
|---|---|---|---|---|---|
| 14 (Sim.) | 1.44 | Ω | 347.80 | nH | 30.29 |
| 14 (Meas.) | 1.52 ± 0.04 | Ω | 373.4 ± 2.7 | nH | 31.0 ± 0.6 |
| 18 (Sim.) | 2.39 | Ω | 646.58 | nH | 34.01 |
| 18 (Meas.) | 2.48 ± 0.03 | Ω | 687.0 ± 4.4 | nH | 34.8 ± 0.3 |

sufficiently small (<7%). Such error could be originated from the leads of the coils in the measurements, coarse meshing in 3-dimensional simulation and the thickness variation of PCB copper traces. Nonetheless, the accuracy is adequate here as only the trend and magnetic field direction are decisive. This also offers a systematic study of the RF coils 16 when compared to the solenoid and saddle-shaped coils.

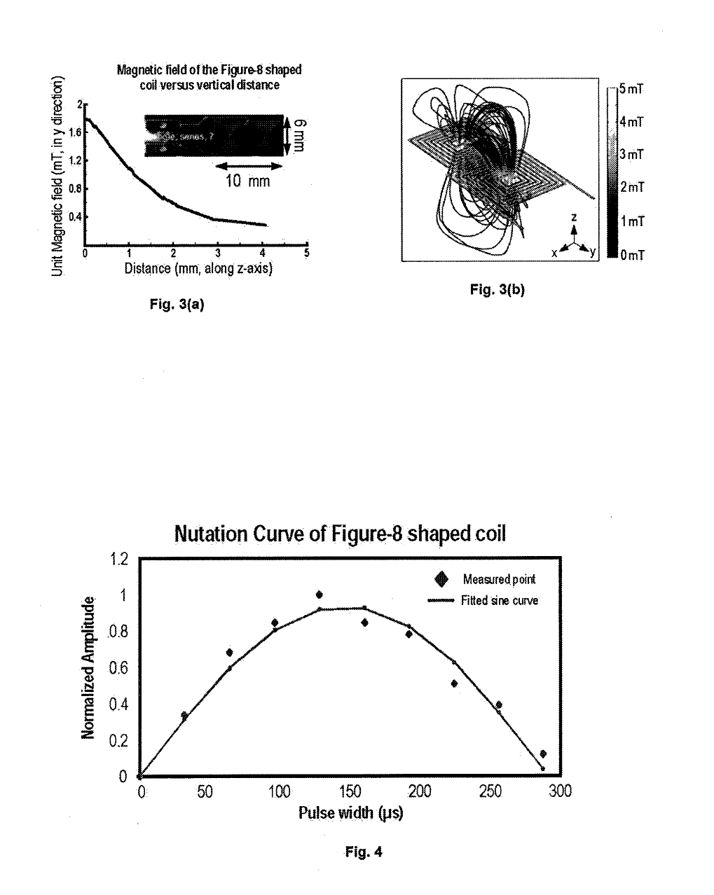

Another advantage of the PCB coils is the reproducibility. From Table 1, the reproducibility of the PCB coils was adequately high as the standard deviations are <3% of the nominal values. This feature makes PCB coils attractive as the fabrication only relies on machines, minimizing the variation between the same styles of coils. The magnetic field strengths of figure-8 shaped coils versus vertical distance were simulated as shown in FIG. 3(a). The magnetic field decays along the z-axis as expected. Thus, to maximize the sensitivity, the samples under test should be closely to the coil's surface according to eqatiuon (2). The unit magnetic field strength is 1.8 mT adequate for the system of the present invention.

Commercial tesla meter (e.g., DTM-150) can only measure AC magnetic field up to 3 kHz. Thus, only simulation results are presented to demonstrate the magnetic field direction of the figure-8 shaped coil under unit current injection. The magnetic-field profile of the 14-turn coil is plotted in FIG. 3(b), where the magnetic flux lines midway the two coils align with the y-direction (i.e., parallel to the PCB surface).

### Electronics

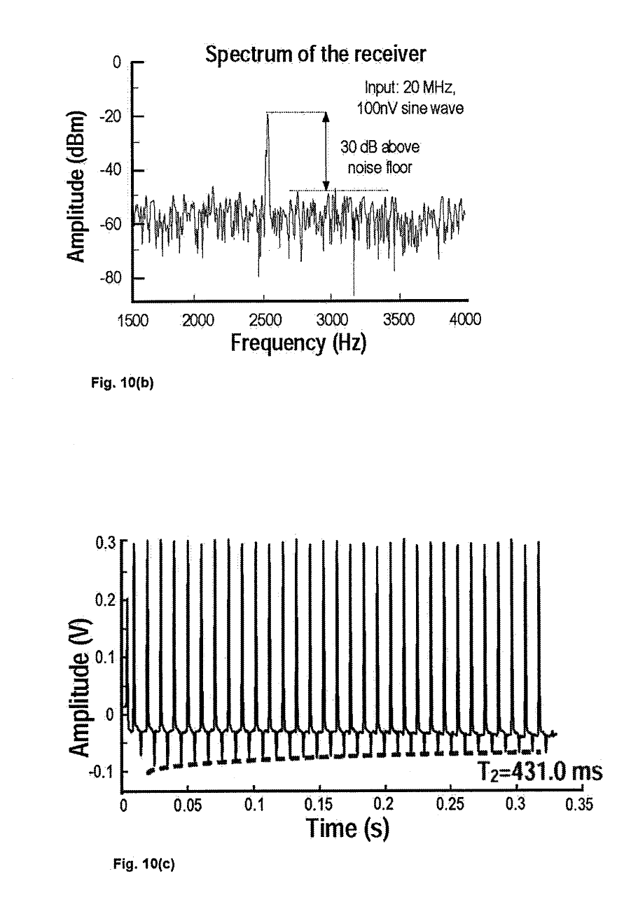

The measured gain of the mixer is 95.7 dB within 5 kHz of IF for the receiver. The output signal of the system with a 100 nV sinusoidal input is 30 dB above the noise floor, and thus it can detect a signal amplitude down to 100 nV. Data pertaining to the electronics measurement can be found in the Electronic Supplementary Information (ESI) text of item 6 below and in FIGS. 10(a) and 10(b).

### NMR Systems

The pulse width of the figure-8 shaped coil was determined by varying the RF excitation pulse duration and observing the corresponding NMR signal. FIG. 4 plots such a nutation curve. The π/2 pulse for the 14-turn figure-8 shaped coil is estimated as 144 μs.

Before integration of the NMR-DMF system, the NMR part was tested separately to verify its own functionality. According to the study, CuSO₄ will affect T₂ of water.³⁹⁻⁴⁰ CuSO₄ with different concentrations was prepared for the experiment. A 14-turn figure-8 shaped coil was selected for the NMR system.

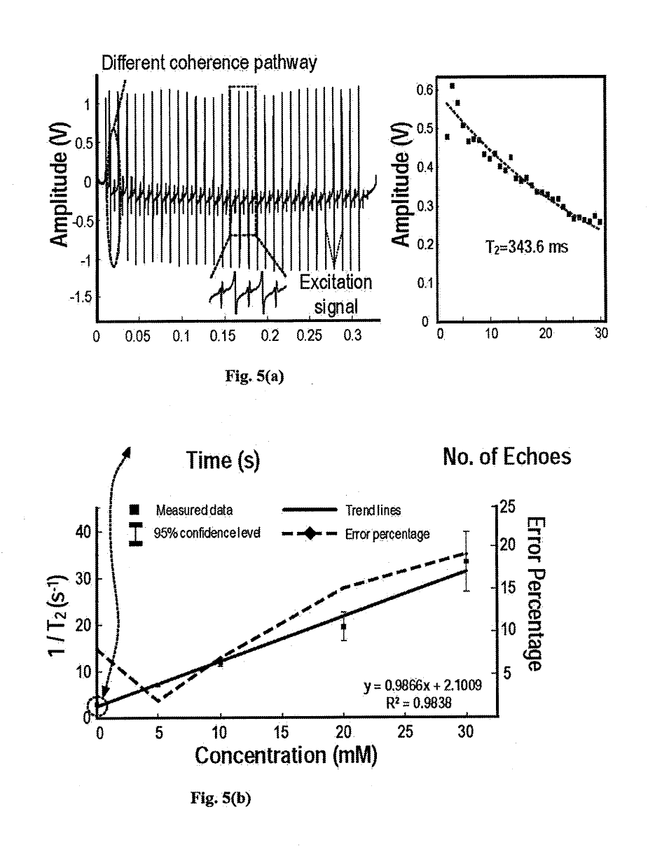

FIG. 5(a) shows the received NMR signal of water from the figure-8 shaped coil 16. T₂ derived by the algorithm is 343.6 ms. The glitches appearing between the echoes correspond to the excitation signal. They can be prevented by adding switches at the receiver front-end. Yet, since this will contribute with noise to the signal they are left together with the echoes. Nevertheless, it will not affect the derivation of T₂ since the algorithm will ignore the excitation signal. Also, the amplitude of the first echo is smaller when compared to the second and third echoes. This is caused by the superposition of different coherence pathways. Since the first echo is severely interrupted by this effect, leading to an amplitude smaller than expected, it will be excluded from the curve fitting algorithm to exclude the error.

The relation between the concentrations of CuSO₄ and T₂ is depicted in FIG. 5(b). 1/T₂ is increased linearly with the concentration of CuSO₄ (0.9866 mM⁻¹s⁻¹).

### Digital Microfluidics Chip

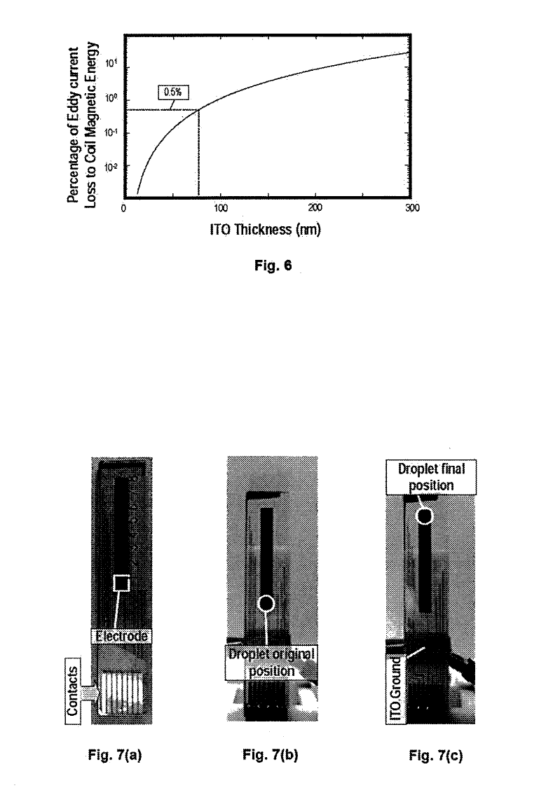

The thickness of the coated ITO can be determined by equation (4). The magnetic energy generated from the 14-turn figure-8 shaped coil unit current is 144 nW. In order to preserve the quality factor of the coil 16, the thickness of the ITO coating should be evaluated. FIG. 6 shows the eddy current loss on the ITO generated by a unit current passing through the 14-turn figure-8 shaped coil against the ITO thickness. The eddy current loss should be diminished less than 0.5% of the magnetic energy generated by the coil, which was marked on FIG. 6. The thickness is limited to 80 nm, which is equivalent to a sheet resistance of 12.5 Ω/sq. The ITO with sheet resistance of 100 Ω/sq. was chosen for the system.

FIG. 7(a) shows the fabricated DMF chip. It consists of only 8 electrodes in a row for this prototype or example embodiment, thus only one assay can be performed each time. Yet, this system can still demonstrate the idea of integrating NMR assays with the DMF platform. FIGS. 7(b) and (c) show the original and final positions of the droplet. The droplet was transported from electrode no. 1 to no. 8, which is the NMR sensing site, by applying a signal on the electrode properly. The velocity of the droplets is ˜1.8 mm/s No obvious distinction of droplet movement was observed with and without a strong magnetic field, as expected, since the DMF works with the electric field for droplet manipulation. Of course, while in this example embodiment 8 electrodes were used, the present invention is not limited to this number of electrodes and more or fewer electrodes could be used.

### Nuclear Magnetic Resonance on Digital Microfluidics Chip

The proposed system integrates two core technologies: NMR and DMF. Integration with the DMF system can enable NMR to be performed in a more automatic and controllable way. Detailed testing result from water can be found in the FIG. 10 (c) (re the Electronic Supplementary Information in Section 6 below).

For biological assays, the NMR-DMF system was operated to test the presence of avidin in the water sample using biotinylated magnetic nanoparticles as a probe. When avidin is absent from the samples, the biotinylated nanoparticles will stay monodispersed. Yet, if avidin exists, avidin and biotin will form rigid bonding and the nanoparticles will aggregate and form large clusters. These clusters will perturb the neighbouring magnetic field and concomitant decrease T₂ of the protons (i.e., decay faster) and thus the NMR system can detect the existence of avidin in real time. The concentration of biotinylated Iron nanoparticle should be well designed. Excessive amount of Iron nanoparticles will diminish the echoes amplitude rapidly (low T₂) and result in difficulty of acquiring the NMR signal. A detailed relationship between concentration of Iron nanoparticle and limit of detection of avidin can be found elsewhere (see, e.g., H. Lee, E. Sun, D. Ham and R. Weissleder, Nat. Med., 2008, 14(8), 869-874).

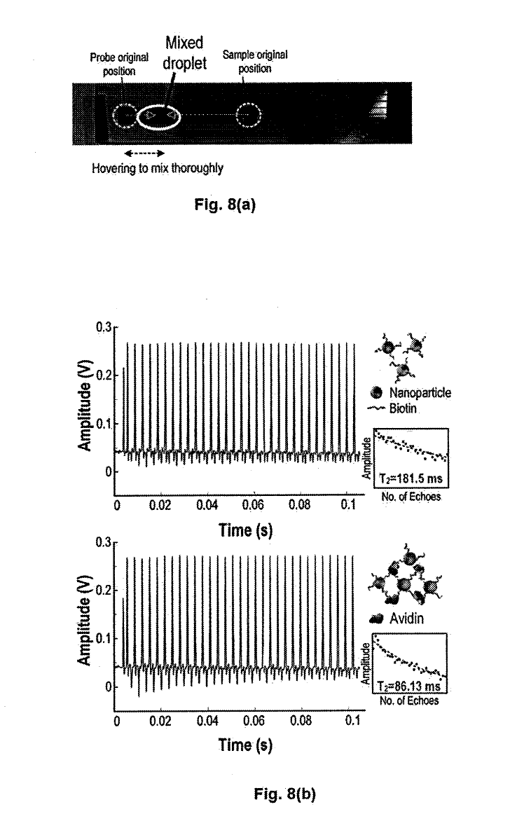

The sample under assay was placed at electrode no. 1 and the probe (droplets with nanoparticles) was placed at electrode no. 8. These two droplets will combine together at electrode no. 7 to form a larger droplet, as shown in FIG. 8(a). To ensure the droplet was mixed thoroughly, it was shuffled between electrode no. 6 and no. 8 several times. Then the droplet was moved to electrode no. 8 for NMR sensing.

FIG. 8(b) shows the received NMR signal with and without avidin. Without avidin in the sample (i.e., the sample only contains water), T₂ of the droplets is 181.5 ms. When avidin presents in the target droplet, it will bind to the biotin and form a larger cluster. Consequently, T₂ of the droplets will be decreased to 86.13 ms, with A T₂ of −52.55%. The error is T₂ of the NMR signals will decrease proportionally to the concentration of the targets in the samples. These results show that the NMR-DMF platform can successfully detect the existence of a specific target in the samples in a fully automatic manner. The results mean that the system can have a technical effect of being a low-cost NMR-based diagnostic tool with high portability and electronic automation.

### 5. Discussion

5.1 Interference from Silicone Oil

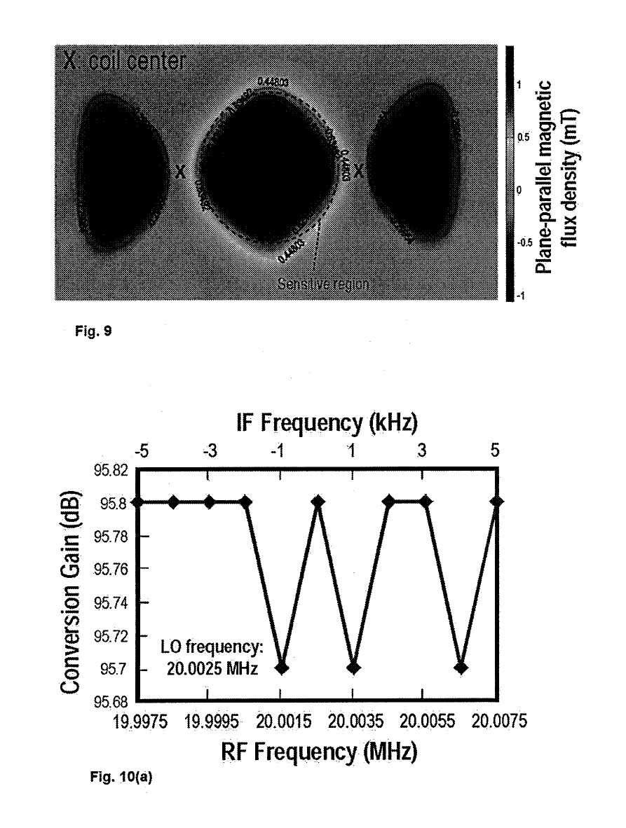

Surrounding the droplet samples via silicone oil is common in DMF to lower the required driving voltage and prevent sample vaporization. However, as silicone oil also contains hydrogen atoms, it will produce NMR signals and their T₂ is comparable to water (oil: 314.5 ms), affecting the sensitivity. To prevent the interference from silicone oil, the figure-8 shaped coil should be designed such that the sensitive region is all covered by the droplets in interest. The sensitive region is midway between the two coils (FIG. 9) that jointly-generate adequate plane-parallel magnetic flux. Outside the region, the magnetic flux is smaller than half of its peak value, rendering the NMR signal weak enough and can be neglected. In consequence, the assay location of the sample should be well-monitored by the DMF chip under real-time feedback control and has a surface area covering the sensitive region, such that the silicone oil cannot affect the result, and the position error becomes more tolerable. Here, the sensitive region of a 14-turn figure-8 shaped coil has a diameter of 4.2 mm, which is fully covered by the droplet having a diameter of 6.3 mm.

### 5.2 Applications

Unlike the spiral coil, the figure-8 shaped coil 16 is capable of generating a plane-parallel RF-field making it a powerful tool to be integrated with the planar DMF chip. The NMR-DMF system can be implemented over a wide variety of applications. Simultaneous detection of multiple biomarkers in a sample is crucial in bio-assays. The system can perform NMR sensing on different sites simultaneously with multiple figure-8 shaped coils since the space available inside the magnet is enlarged. This can deliver a higher throughput which is suitable for drug screening.

Other applications include cell incubation and detection in a DMF platform. This is becoming more attractive in recent years. With the attestation that DMF has negligible effect on the vitality and characteristics of the cells, it is favourable for operation with mass-limited cell samples. Typical cell characteristics assays on DMF include absorbance test, fluorescence, surface plasmon resonance, and impedance sensing. Those methods either require bench-top equipment (fluorescence, surface plasmon resonance), have limited sensitivity (absorbance test), or are non-specific (impedance sensing). On the other hand, NMR could be more promising for cell targeting and quantitative analysis, including cancer cells for early cancer diagnosis and it can provide high sensitivity assays. Yet, before NMR operation, a series of manual preparation steps (e.g., cell culturing) had to be performed. With the described NMR-DMF system, NMR assays can be done with minimal human operations. DMF platform may include a culturing site for cell culturing within DMF. Thus, all operations can be well-guided by the computer.

Similarly, Deoxyribonucleic acid (DNA) can also be amplified on the DMF platform. This can reduce the operation time and samples consumption when compared with bench-top PCR machines. However, the detection method of those on-chip PCR mainly relies on general gel electrophoresis, which could not be integrated with the DMF platform. On the other hand, NMR assays are able to perform sensitive DNA/oligonucleotide targeting, including practical applications such as the detection of pathogen, bacteria, and fungus in the whole blood. With the NMR-DMF system of the present invention, the human operation can be greatly simplified. The DNA amplification and targeting in NMR can be done inside the chip without human effort such that the detection time and chance of contamination can be minimized.

### 6. Electronic Supplementary Information (ESI)

### NMR Electronics Components and Measurement

The forefront amplifier of the NMR receiver in this example embodiment is VCA2615 from Texas Instruments (Dallas, Tex.). It features a high input impedance of >100 kΩ and is with a variable-gain control in the 52 dB range. An operational amplifier OPA842 from Texas Instruments (Dallas, Tex.) was employed to provide additional gain and convert the differential signal into single-ended for frequency down-conversion. Mixers TUF-3HSM+ from Mini-Circuits (Brooklyn, N.Y.) were chosen as the down-mixing module. The NMR transmitter was constructed by simple digital electronics (Flip-flops, switches, and buffers) which are products from Texas Instruments (Dallas, Tex.).

The electrical performances of the NMR electronics were characterized before sample measurements. FIG. 10(a) shows the measured gain of an NMR receiver according to this example embodiment of the present invention. Sinusoidal RF signals with a frequency from 19.9975 to 20.0075 MHz were injected into the receiver and a reference local oscillator (LO) signal of 20.0025 MHz was provided for the mixer. The gain of the overall system was stable around 95.7 to 95.8 dB within ±5 kHz of the intermediate frequency (IF). The gain can be further boosted by increasing the gain of the IF low-pass filter.

FIG. 10(b) shows the measured output spectrum of a receiver with a 100 nV, 20 MHz sinusoidal input according to an example embodiment of the invention. That is, for the sensitivity of the receiver, the spectrum of the received signal was plotted in FIG. 10(b) shows 10(b). A 100 nV sinusoidal signal at 20 MHz was injected into the receiver. This amplitude is similar to the amplitude of the NMR stated in Section 2. The frequency of the LO was set at 20.0025 MHz and results in an IF frequency of 2.5 kHz. The resulting signal contains a fundamental tone with amplitude of −20 dBm at 2.5 kHz. The noise floor is 30 dB below the injected signal. Thus the receiver is capable to detect a signal with the amplitude down to 100 nV.

FIG. 10(c) shows a received NMR signal of water. The T₂ extraction result (431.0 ms) shows that it is similar to the case without the DMF platform. This indicates that the system performs at least as well as a conventional NMR system.

### 7. Example Implementations

The present invention or various part(s) or function(s) thereof may be implemented using hardware, software, or a combination thereof, and may be implemented in one or more computer systems or other processing systems. A computer system for performing various operations of the present invention and capable of carrying out the functionality described herein can include one or more processors connected to a communications infrastructure (e.g., a communications bus, a cross-over bar, or a network). Various software embodiments are described in terms of such an exemplary computer system. After reading this description, it will become apparent to a person skilled in the relevant art(s) how to implement the invention using other computer systems and/or architectures.

The computer system can include a display interface that forwards graphics, text, and other data from the communication infrastructure (or from a frame buffer) for display on a display unit. The display interface can communicate with a browser. The computer system also includes a main memory, preferably a random access memory, and may also include a secondary memory and a database. The secondary memory may include, for example, a hard disk drive and/or a removable storage drive, representing a floppy disk drive, a magnetic tape drive, an optical disk drive, etc. The removable storage drive reads from and/or writes to a removable storage unit in a well known manner. The removable storage unit can represent a floppy disk, magnetic tape, optical disk, etc. which is read by and written to by the removable storage drive. As will be appreciated, the removable storage unit can include a computer usable storage medium having stored therein computer software and/or data.

The computer system may also include a communications interface which allows software and data to be transferred between the computer system and external devices. The terms “computer program medium” and “computer usable medium” are used to refer generally to media such as the removable storage drive, a hard disk installed in the hard disk drive, and signals. These computer program products provide software to the computer system.

Computer programs or control logic are stored in the main memory and/or the secondary memory. Computer programs may also be received via the communications interface. Such computer programs or control logic (software), when executed, cause the computer system or its processor to perform the features and functions of the present invention, as discussed herein.

### 8. Conclusions

In summary, modular integration of NMR and DMF has been demonstrated. The present invention can overcome the geometrical limitations among the traditional spiral coil, planar DMF chip, and portable magnet by introducing a figure-8 shaped coil, which could be fabricated with a low-cost PCB having high reproducibility. Extensive studies and experiments verified the compatibility and co-functionality of the two distinctive technologies: NMR (assay tool) and DMF (droplet sample operation). The electronic-automated real-time identification of avidin/biotinylated magnetic nanoparticles pairs proved the biological assay capability of the system. Compared to the micro-channel NMR, this system improves droplet management allowing multi-step screening protocols guided by simple electronics. Potential applications such as DNA amplification and detection were also discussed, showing that such a NMR-DMF system can be extended to different biological applications.

While the invention has been particularly shown and described with respect to preferred embodiment(s) thereof, it should be understood that the embodiment(s) have been presented by way of example, and not limitation. It will be apparent to persons skilled in the relevant art(s) that various changes in form and detail can be made therein without departing from the spirit and scope of the present invention. Thus, the present invention should not be limited by any above-described exemplary embodiment, but should be defined only in accordance with the following claims and their equivalents.

In addition, it should be understood that the figures illustrated in the attachments, which highlight the functionality and advantages of the present invention, are presented for example purposes only. The architecture of the present invention is sufficiently flexible and configurable, such that it may be utilized (and navigated) in ways other than that shown in the accompanying figures.

Furthermore, the purpose of the foregoing Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The Abstract is not intended to be limiting as to the scope of the present invention in any way. It is also to be understood that the steps and processes recited in the claims need not be performed in the order presented.

Having described the invention, what is claimed as new and secured by Letters Patent is:

1. A portable modular Nuclear Magnetic Resonance-Digital Microfluidic (NMR-DMF) system for performing chemical/biological assays, comprising:
a printed circuit board (PCB) having an NMR electronic circuit thereon, wherein the NMR electronic circuit includes a figure-8 shaped RF coil generating a plane-parallel magnetic field;
a planar DMF chip comprising a platform comprising an array of electrodes using electro-wetting-on-dielectric (EWOD) effects, the array of electrodes including a sensing site located under the figure-8 shaped RF coil and having top and bottom planes for squeezing droplets; and
a portable magnet disposed parallel to the DMF chip and the RF coil,
wherein in said planar DMF chip a first electrode in the electrode array is configured to initially receive a sample under detection, and a last electrode in the electrode array is configured to act as the sensing site and to initially receive a probe in the form of at least one droplet with target-specific nanoparticles,
wherein said planar DMF chip is configured to transport a sample under detection from the first electrode to the sensing site using an operation sequence including (1) initially applying a signal on the first electrode, then (2) turning off the first electrode thereby moving the sample to a subsequent electrode, and (3) repeating said operation sequence to ultimately move the sample to the sensing site after a mixing sequence,
wherein said planar DMF chip uses said mixing sequence to mix the sample with the probe placed on the sensing site before the mixed sample is finally moved to the sensing site,
wherein a magnetic field corresponding to the mixed sample under detection is produced at the sensing site,
wherein the figure-8 shaped RF coil serves as an interface between the mixed sample at the sensing site and the NRM electronic circuit and acts to transduce the magnetic field produced at the sensing site to a voltage signal, and
wherein the NMR electronic circuit receives and processes the voltage signal to produce a resultant signal for analysis.

2. The system of claim 1, wherein the NRM electronics on the PCB comprise:
a receiver, configured to receive the voltage signal provided by the figure-8 shaped RF coil, the receiver having switches to isolate the excitation voltage signal from the transmitter and a capacitor which together with the RF coil forms an LC tank to amplify the voltage signal to provide a passive gain to the voltage signal, after which the amplified signal is sent to an operational amplifier for additional gain and conversion into a single-ended signal, after which the signal is down-converted by I and Q mixers to an intermediate frequency in order to filter high-frequency noise superimposed into the signal, after which the down-converted signal is low-pass filtered and then is further amplified, after which the signal is sent to an external filter and an oscilloscope for display and analysis; and
a transmitter comprising output buffers to boost driving capability, and a field-programmable gate array (FPGA) to control operating phases of the switches and output buffers.

3. The system of claim 1, wherein said operation sequence further includes surrounding the sample with silicone oil when the sample is initially placed on the first electrode.

4. The system of claim 1, wherein said mixing sequence includes (1) mixing the probe with the sample to form the mixed sample when the sample reaches a penultimate electrode, (2) shuffling the mixed sample between (a) the electrode located before the penultimate electrode and (b) the last electrode a plurality of times for more thorough mixing, and (3) finally transporting the mixed sample to the last electrode for NMR sensing.

5. The system of claim 1, wherein the array of electrodes on the platform of the planar DMF chip has 8 electrodes.

6. The system of claim 1, wherein said DMF chip is equipped to receive the sample under detection, the sample comprising one or more droplets including chemical/biological constituents and targets.

7. The system of claim 1, wherein the electrodes in the array of the DMF chip are formed of chromium.

8. The system of claim 1, wherein the figure-8 shaped RF coil is a planar coil.

9. The system of claim 8, wherein the planar coil is a circular spiral.

10. The system of claim 1, wherein the figure-8 shaped RF coil is comprised of two spiral coils in reverse direction in series.

11. The system of claim 10, wherein the figure-8 shaped RF coil has a sensitive region midway between the two spiral coils that is configured to be covered by the sample.

12. The system of claim 1, wherein the steps of said operation sequence are stored in a computer program embodied in a non-transitory computer-readable medium for execution by a processor.

13. The system of claim 4, wherein the steps of said mixing sequence are stored in a computer program embodied in a non-transitory computer-readable medium for execution by a processor.

14. The system of claim 1, wherein the first electrode of the array of the planar DMF chip is configured to receive a pre-loaded sample.

15. The system of claim 1, wherein the platform of the planar DMF chip further comprises:
a first glass substrate;
a Ta205 layer on the glass substrate;
a Parylene-C layer on the Ta205 layer;
the array of electrodes on the Parylene-C layer;
an Indium Tin Oxide (ITO) layer above the array of electrodes, acting as a ground plane; and
a second glass substrate on the ITO layer.

16. The system of claim 1, wherein each electrode in the array is driven by a square wave driving signal while each neighboring electrode is grounded to prevent excess charges stored in the electrodes.

17. The system of claim 1, further comprising at least one additional figure-8 shaped RF coil corresponding to at least one additional planar DMF chip for simultaneous sensing at multiple sites.

18. A portable modular Nuclear Magnetic Resonance-Digital Microfluidic (NMR-DMF) system for performing chemical/biological assays, comprising:
a printed circuit board (PCB) having an NMR electronic circuit thereon, wherein the NMR electronic circuit includes a figure-8 shaped RF coil generating a plane-parallel magnetic field;
a planar DMF chip comprising a platform comprising an array of electrodes, the array of electrodes including a sensing site located under the figure-8 shaped RF coil; and
a portable magnet disposed parallel to the DMF chip and the RF coil,
wherein said array of electrodes is configured to receive a sample under detection, move the sample along the array, mix the sample with a probe in the form of at least one droplet with target-specific nanoparticles, and move the mixed sample to the sensing site,
wherein a magnetic field corresponding to the mixed sample under detection is produced at the sensing site,
wherein the figure-8 shaped RF coil acts to transduce the magnetic field produced at the sensing site to a voltage signal, and
wherein the NMR electronic circuit receives and processes the voltage signal to produce a resultant signal for analysis.

19. The system of claim 18, wherein said array of electrodes is further configured to surround the sample with silicone oil when the sample is initially placed on the first electrode.

20. A method for performing chemical/biological assays using a portable modular Nuclear Magnetic Resonance-Digital Microfluidic (NMR-DMF) system comprising a printed circuit board (PCB) having an NMR electronic circuit thereon, wherein the NMR electronic circuit includes a figure-8 shaped RF coil generating a plane-parallel magnetic field; a planar DMF chip comprising a platform comprising an array of electrodes, the array of electrodes including a sensing site located under the figure-8 shaped RF coil; and a portable magnet disposed parallel to the DMF chip and the RF coil, said method comprising the steps of:
placing a sample at a first electrode in said array of electrodes;
moving the sample along said array;
mixing the sample with a probe in the form of at least one droplet with target-specific nanoparticles;
moving the mixed sample to the sensing site at a last electrode of said array,
producing a magnetic field corresponding to the mixed sample under detection at the sensing site;
transducing by the figure-8 shaped RF coil the magnetic field produced at the sensing site to a voltage signal; and
processing the voltage signal by the NMR electronic circuit to produce a resultant signal for analysis.

21. The method of claim 20, further comprising surrounding the sample with silicone oil when the sample is initially placed on the first electrode.

22. The method of claim 20, wherein said mixing step includes (1) mixing the probe with the sample to form the mixed sample when the sample reaches the penultimate electrode, (2) shuffling the mixed sample between (a) the electrode located before a penultimate electrode and (b) the last electrode a plurality of times for more thorough mixing, and (3) transporting the mixed sample to the last electrode for NMR sensing.

23. A non-transitory computer-readable medium storing a program which, when executed by at least one processor, performs a method for performing chemical/biological assays using a portable modular Nuclear Magnetic Resonance-Digital Microfluidic (NMR-DMF) system comprising a printed circuit board (PCB) having an NMR electronic circuit thereon, wherein the NMR electronic circuit includes a figure-8 shaped RF coil generating a plane-parallel magnetic field; a planar DMF chip comprising a platform comprising an array of electrodes, the array including a sensing site located under the figure-8 shaped RF coil, a first electrode in the array being configured to initially receive a sample under detection and a last electrode in the array being configured to act as the sensing site and to initially receive a probe in the form of at least one droplet with target-specific nanoparticles; and a portable magnet disposed parallel to the DMF chip and the RF coil, said method comprising the steps of:
performing an operation sequence comprising applying a signal on the first electrode and then turning off the first electrode thereby moving the sample to a subsequent electrode;
repeating said operation sequence for each subsequent electrode to move the sample to a penultimate electrode;
performing a mixing sequence to (1) mix the probe with the sample to form the mixed sample when the sample reaches the penultimate electrode, and (2) shuffle the mixed sample between (a) the electrode located before the penultimate electrode and (b) the last electrode a plurality of times for more thorough mixing; and
transporting the mixed sample to the last electrode for NMR sensing.
